(19) United States
(12) Patent Application Publication
(10) Pub. No.: US 2003/0189249 A1
(43) Pub. Date: Oct. 9, 2003

(54) CHIP STRUCTURE AND WIRE BONDING PROCESS SUITED FOR THE SAME

(76) Inventors: Ho-Ming Tong, Taipei (TW); Chun-Chi Lee, Kaohsiung (TW); Jen-Kuang Fang, Pingtung Hsien (TW); Min-Lung Huang, Kaohsiung (TW); Ching-Huei Su, Kaohsiung (TW); Chao-Fu Weng, Tainan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,027

(22) Filed: Mar. 11, 2003

(30) Foreign Application Priority Data
Apr. 3, 2002 (TW) 91106693

(51) Int. Cl. H01L 23/48

(52) U.S. Cl. 257/737; 257/750; 257/762; 257/784; 438/614; 438/617

(57) ABSTRACT

A chip structure having a chip, an adhesion layer, and a metal layer. The chip has an active surface and many conductive pads. The conductive pads are disposed on the active surface, wherein the conductive pads are made of copper. The adhesion layer is directly formed on the conductive pads, wherein the material of the adhesion layer includes copper. The metal layer is formed on the adhesion layer, wherein the material of the metal layer includes copper.

### CROSS REFERENCE TO RELATED APPLICATIONS

This application claims the priority benefit of Taiwan application serial no. 91106693, filed Apr. 03, 2002.

### BACKGROUND OF INVENTION

1. Field of the Invention

The present invention is generally related to a chip structure, and particularly to a chip structure that increases reliability during wire bonding.

2. Description of Related Artl

In the modern communications-bursting world, integrated circuits (ICs) have become an important part of life. No matter in any aspects of life, we usually come across the finished product of an IC. Rapid evolution and humanization of electronics technology have created a lot of feature-packed and complex electronic products which are lighter, smaller, shorter, and thinner in design for providing consumers with convenience and comfort. In semiconductor design, the line width of circuits has already reached 0.18 microns and is continuing to miniaturize to 0.15 microns and even 0.13 microns.

As the dimensions of the wires decrease, the size of the conductive pads has to be corresponding reduced. As a result, serious problems occur when connecting the miniaturized wires to their corresponding conductive pads. Furthermore problem such as peeling of the conductive pads from the chip occurs during wire bonding or another problem such as conductive pads being damaged occurs during wire bonding. These problems prevent the conductive pads from properly and electrically connecting to the inner wires of the chip.

### SUMMARY OF INVENTION

An object of the present invention is to provide a chip structure that increases the reliability of the chip structure during the wire bonding process.

This following paragraph defines the lexicography used in this specification. The location modifier “top” in this specification can indicate that two objects are in direct or indirect contact with each other. For example, if object A is on top of object B, it means that object A is directly placed on top and in contact with object B; and if object A is not in contact with object B, it means that object A is placed above but not in directly contact with object B.

In order to meet the above objects, the present invention provides a chip structure comprising a chip, an adhesion layer, and a metal layer. Wherein the chip has an active surface and a plurality of conductive pads located on the active surface of the chip, and the material of the conductive pads is copper. The adhesion layer is formed directly on top of the conductive pads and the material of the adhesion layer is copper. The metal layer is located on top of the adhesion layer and the material of the metal layer is copper.

In order to meet the above objects, the present invention also provides a wire bonding process. A chip having an active surface and a plurality of conductive pads located on the active surface of the chip is provided. Afterwards, an adhesion layer is formed on top of the active surface of the chip. The material of the adhesion layer can be copper, chromium copper alloy or tin copper alloy. Following, a photoresist layer is formed on top of the adhesion layer where the photoresist layer has at least one photoresist opening exposing the adhesion layer. Afterwards, a metal layer is formed in the photoresist opening on top of the adhesion layer where the material of the metal layer can be copper, chromium copper alloy or tin copper alloy. Next the photoresist layer is removed. Then the adhesion layer that is outside the metal layer is removed. At last, one end of the conductive wire is connected to the metal layer.

In order to meet the above objects, the present invention provides a wire bonding process. A chip having an active surface and a plurality of conductive pads located on the active surface of the chip is provided. Afterwards, an adhesion layer is formed on top of the active surface of the chip. The material of the adhesion layer can be copper, chromium copper alloy or tin copper alloy. Following, a metal layer is formed on top of the adhesion layer and the material of the metal layer can be copper, chromium copper alloy or tin copper alloy. Afterwards, a photoresist is formed on top of the metal layer where the photoresist layer has at least one photoresist opening exposing the metal layer. Next the metal layer outside the photoresist opening is removed. Then the adhesion layer outside of the metal layer is removed. Following the photoresist layer is removed. At last, one end of the conductive wire is connected to the metal layer.

According to the aforementioned, the chip structure of the present invention has the conductive wires formed on top of the metal layer to prevent damage of the conductive pads during wire bonding for increasing electrical properties. Furthermore, the adhesion layer and the metal layer formed on top of the conductive pads prevent peeling of the conductive pads during wire bonding. As a result, the reliability of the wire bonding process is significantly improved.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings, F

FIG. 1 to FIG. 7 are schematic diagrams of enlarged sectional views of the wafer layers according to the first embodiment of the present invention.

FIG. 8 to FIG. 11 are schematic diagrams of enlarged sectional views of the wafer layers according to the second embodiment of the present invention.

### DETAILED DESCRIPTION

FIG. 1 to FIG. 7 are schematic diagrams of enlarged sectional views of the wafer layers according to the first embodiment of the present invention. Please refer to FIG. 1, a wafer 110 is provided. The wafer 110 has an active surface 12, a passivation layer 114, and a plurality of conductive pads 116. The conductive pads 116 are located on the active surface 112 of the wafer 110 and the passivation layer 114 expose the conductive pads, wherein the material of the conductive pads 116 comprises copper. Furthermore the wafer 110 can be divided into a plurality of chips, whereby these chips are arranged in an array. FIG. 1 to FIG.7 show the bonding area of a single chip obtained from the wafer. After the wafer 110 is provided, the conductive pads 116 can be cleaned using an acidity solution whereby the impurities attached onto the conductive pads 116 can be removed.

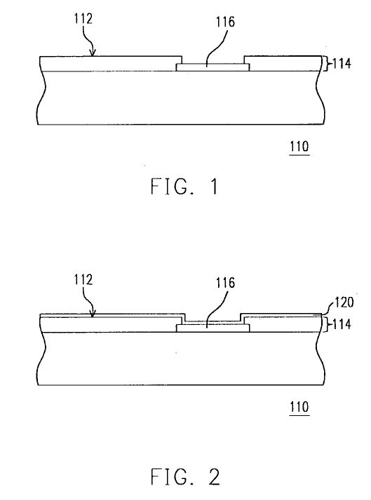

Please refer to FIG. 2, an adhesion layer is deposited. An adhesion layer 120 is formed on the active surface 112 of the wafer 110 by evaporating, sputtering or electro-less plating. The adhesion layer 120 covers the conductive pads 116 and the passivation layer 114, wherein the material of the adhesion layer 120 is gold, platinum, palladium, silver, copper, chromium copper alloy or tin copper alloy.

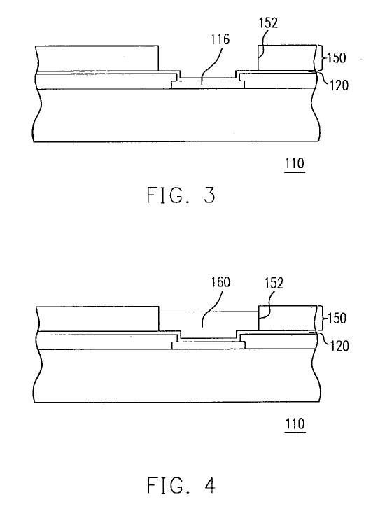

Please refer to FIG. 3, a photolithography process is performed. A photoresist layer 150 is formed on top of the adhesion layer 120. After exposure and developing, a pattern (not shown) is transferred to the photoresist layer 150 allowing the formation of a plurality of photoresist openings 152 (only one is shown in the drawing) for exposing the locations of the conductive pads 116 on the adhesion layer 120.

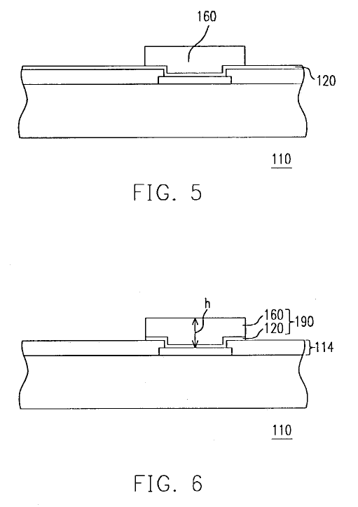

Please refer to FIG. 4, a filling process is performed. A metal layer 160 is formed on top of the adhesion layer 120 inside the opening 152 and the material of the metal layer 160 comprises gold, platinum, palladium, silver, copper, chromium copper alloy or tin copper alloy. Afterwards, a photoresist layer removal process is performed to remove the photoresist layer 150 from the adhesion layer 120, as illustrated in FIG. 5. Following, an adhesion layer removal process is performed for example by etching. The metal layer 160 acts as a mask when removing the adhesion layer 120 that is exposed outside the metal layer 160. The removal continues until the passivation layer 114 of the wafer 110 is exposed and then the only remaining of the adhesion layer 120 is underneath the metal layer 160, as illustrated in FIG. 6. The fabrication of the metal protection layer 190 is therefore complete, wherein the metal protection layer 190 comprises the adhesion layer 120 and the metal layer 160. The thickness “h” (representing the total thickness of both the adhesion layer and the metal layer) of the metal protection layer 190 is between 1 micron to 1000 micron. Finally the wafer 110 is singularized to become individual chips. These chips will be coupled to a carrier (not shown) such as a leadframe or a substrate.

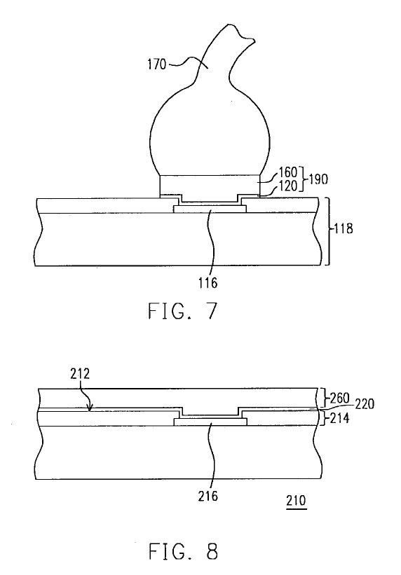

Please refer to FIG. 7, a conductive wire 170 is bonded so the chip 118 and the carrier are electrically connected by the conductive wire 170. Wherein one end of the conductive wire is coupled to the metal layer 160 and the other end of the conductive wire 170 is coupled to the connection pad of the carrier.

Please refer to FIG. 7, the damage to the conductive pads 116 is prevented because the conductive wire 170 is bonded to the metal layer 160 so to improve electrical properties. Furthermore the metal protection layer 190 on top of the conductive pads 116 prevents peeling of the conductive pads 116 during wire bonding of the conductive wire 170. As a result the reliability of the wire bonding process is significantly increased.

Furthermore the process of the metal protection layer does not limit to the aforementioned, and other methods are also acceptable. In the following, FIG. 8 to FIG. 11 are schematic diagrams of enlarged sectional views of the wafer layers according to the second embodiment of the present invention. Please refer to FIG. 8, an adhesion layer 220 is formed on the active surface of a wafer 210 by evaporating, sputtering or electro-less plating. The adhesion layer 220 covers the conductive pads 216 and the passivation layer 214, wherein the material of the adhesion layer 220 comprises gold, platinum, palladium, silver, copper, chromium copper alloy or tin copper alloy. Following, a metal layer 260 is formed on top of the adhesion layer 220 by evaporating, sputtering or electro-less plating, wherein the material of the metal layer 260 comprises gold, platinum, palladium, silver, copper, chromium copper alloy or tin copper alloy.

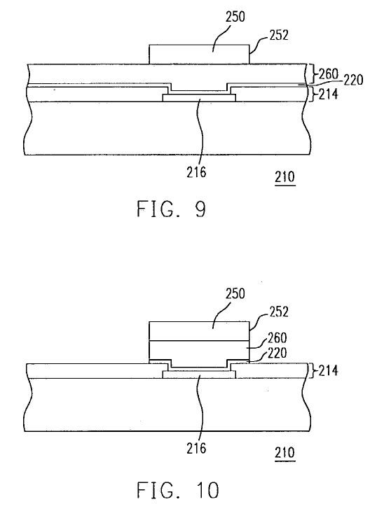

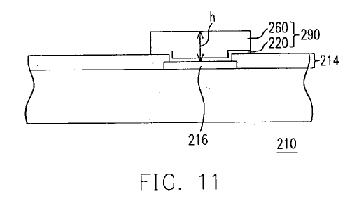

Please refer to FIG. 9, a photolithography process is performed. A photoresist layer 250 is formed on top of the metal layer 260. After exposure and developing, a pattern (not shown) is transferred to the photoresist layer 250 allowing the formation of a plurality of photoresist openings 252 which expose the metal layer 260. The remaining of the photoresist layer 250 is left on the metal layer 260 on top of the conductive pads 216. A metal layer removal process is performed for example by etching, where the remaining of the photoresist layer 250 is used as a mask for covering the photoresist opening 252 when removing the metal layer 260 and the adhesion layer 220. The process continues until the passivation layer 214 of the wafer 210 is exposed, as illustrated in FIG. 10. The fabrication of the metal protection layer 290 is therefore complete, wherein the metal protection layer 290 comprises the adhesion layer 220 and the metal layer 260. The thickness “h” (representing the total thickness of both the adhesion layer and the metal layer) of the metal protection layer 290 is between 1 micron to 1000 micron. Finally the wafer 210 is singularized to become individual chips. These chips will be coupled to a carrier (not shown) such as a leadframe or a substrate. The process herein onwards is identical to the aforementioned and will not be repeated.

In the above process, if the thickness of the metal protection layer is relatively thin, the metal protection layer can be formed directly by evaporating, sputtering or electro-less plating. If the thickness of the metal protection layer is relatively thick, the metal protection layer can be formed by combining the adhesion layer formed by evaporating, sputtering or electro-less plating and the metal layer formed by electroplating.

The present invention uses the conductive pads of a chip as the external connecting points and the metal protection layer of the present invention does not limit its application to only the conductive pads of the chip but can be applied to any connectors. The metal protection layer can be used for forming connecting points on a PCB board or can be used for redistribution of the layer by matching the connecting points of the metal protection layer and the redistribution layer, these methods are well known in the skilled of the art and will not be disclosed in details.

Summarizing the above, the present invention has the following advantages:1

1. The chip structure of the present invention prevents damage to the conductive pads because the conductive wires are formed on the metal layer to increase electrical properties.

2. The chip structure of the present invention prevents the peeling of the conductive pads by forming a metal protection layer on the conductive pads to increase the reliability of wire bonding.

It will be apparent to those skilled in the art that various modifications and variations can be made to the structure and method of the present invention without departing from the scope or spirit of the present invention. In view of the foregoing description, it is intended that the present invention covers modifications and variations of this invention provided they fall within the scope of the following claims and their equivalents.

1. A chip structure, suited for being connected with a plurality of conductive wires, comprising:
a chip having an active surface and a plurality of conductive pads located on the active surface of the chip;
an adhesion layer formed on the conductive pads; and
a metal layer located on the adhesion layer and connected with the conductive wires.

2. The chip structure in claim 1, wherein the material of the adhesion layer is gold, platinum, palladium, silver, copper, chromium copper alloy or tin copper alloy.

3. The chip structure in claim 1, wherein the material of the metal layer is gold, platinum, palladium, silver, copper, chromium copper alloy or tin copper alloy.

4. The chip structure in claim 1, wherein the material of the conductive pads comprises copper.

5. The chip structure in claim 1, wherein a total thickness of both the metal layer and the adhesion layer is between 1 micron and 1000 microns.

6. A chip structure, suited for being connected with a plurality of conductive wires, comprising:
a chip having an active surface and a plurality of conductive pads located on the active surface of the chip; and
a metal protection layer located on the conductive pads and connected with the conductive wires.

7. The device in claim 6, wherein the configuration of the metal protection layer is a gold layer, a platinum layer, a palladium layer, a silver layer, a copper layer, a chromium-copper-alloy layer, a tin-copper-alloy layer or compound layers constructed of the above-mentioned materials.

8. The device in claim 6, wherein the material of the conductive pads comprises copper.

9. The device in claim 6, wherein the thickness of the metal protection layer is between 1 micron and 1000 microns.

10. A structure for connecting a conductive wire and an electrical connection, comprising:
an electrical connection;
a metal protection layer formed on the electrical connection; and
a conductive wire coupled to the metal protection layer.

11. The structure in claim 10, wherein the configuration of the metal protection layer is a gold layer, a platinum layer, a palladium layer, a silver layer, a copper layer, a chromium-copper-alloy layer, a tin-copper-alloy layer or compound layers constructed of the above-mentioned materials.

12. The structure in claim 10, wherein the metal protection layer comprises an adhesion layer and a metal layer, the metal protection layer formed on the adhesion layer, the adhesion layer formed on the electrical connection, and the metal layer coupled to the conductive wire.

13. The structure in claim 12, wherein the material of the adhesion layer is gold, platinum, palladium, silver, copper, chromium copper alloy or tin copper alloy.

14. The structure in claim 12, wherein the material of the metal layer is gold, platinum, palladium, silver, copper, chromium copper alloy or tin copper alloy.

15. The structure in claim 10, wherein the thickness of the metal protection layer is between 1 micron and 1000 microns.

16. A wire-bonding process, comprising:
providing a chip with an active surface and at least one conductive pad located on the active surface;
forming an adhesion layer on the active surface and the conductive pad of the chip;
forming a photoresist layer on the adhesion layer, wherein the photoresist layer has at least one opening exposing the adhesion layer positioned on the conductive pad;
forming a metal layer in the opening of the photoresist layer and the metal layer formed on the adhesion layer;
removing the photoresist layer;
removing the adhesion layer exposed to the outside; and
coupling one end of a conductive wire to the metal layer positioned over the conductive pad.

17. The process of claim 16, wherein a method of forming the adhesion layer on the active surface and the conductive pad of the chip is selected from a group consisting of evaporating, sputtering, and electro-less plating.

18. The process of claim 16, wherein the metal layer is formed in the opening of the photoresist layer by an electroplating method.

19. The process in claim 16, wherein the material of the adhesion layer is gold, platinum, palladium, silver, copper, chromium copper alloy or tin copper alloy.

20. The process in claim 16, wherein the material of the metal layer is gold, platinum, palladium, silver, copper, chromium copper alloy or tin copper alloy.

21. The process of claim 16, wherein the material of the conductive pad comprises copper.

22. The process of claim 16, wherein the total thickness of both the metal layer and the adhesion layer is between 1 micron and 1000 microns.

23. Awire-bonding process, comprising:
providing a chip with an active surface and at least one conductive pad located on the active surface;
forming an adhesion layer on the active surface and the conductive pad of the chip;
forming a metal layer on the adhesion layer;
forming a photoresist layer on the metal layer, wherein the photoresist layer has at least one opening exposing the metal layer not positioned over the conductive pad;
removing the metal layer exposed to the outside;
removing the adhesion layer exposed to the outside;
removing the photoresist layer; and
coupling one end of a conductive wire to the metal layer positioned over the conductive pad.

24. The process of claim 23, wherein a method of forming the adhesion layer on the active surface and the conductive pad of the chip is selected from a group consisting of evaporating, sputtering, and electro-less plating.

25. The process of claim 23, wherein a method of forming the metal layer on the adhesion layer is selected from a group consisting of electroplating, evaporating, sputtering, and electro-less plating.

26. The process in claim 23, wherein the material of the adhesion layer is gold, platinum, palladium, silver, copper, chromium copper alloy or tin copper alloy.

27. The process in claim 23, wherein the material of the metal layer is gold, platinum, palladium, silver, copper, chromium copper alloy or tin copper alloy.

28. The process of claim 23, wherein the material of the conductive pad comprises copper.

29. The process of claim 23, wherein the total thickness of both the metal layer and the adhesion layer is between 1 micron and 1000 microns.

30. A wire-bonding process, comprising:
providing an electrical connection;
forming a metal protection layer on the electrical connection; and
coupling one end of the conductive wires to the metal layer.

31. The process in claim 30, wherein the material of the electrical connection comprises copper.

32. The structure in claim 30, wherein the configuration of the metal protection layer is a gold layer, a platinum layer, a palladium layer, a silver layer, a copper layer, a chromium-copper-alloy layer, a tin-copper-alloy layer or compound layers constructed of the above-mentioned materials.

33. The process of claim 30, wherein the thickness of the metal protection layer is between 1 micron and 1000 microns.
